(19) United States
(12) Patent Application Publication
(10) Pub. No.: US 2007/0045860 A1
(43) Pub. Date: Mar. 1, 2007

(54) Semiconductor device and method for fabricating the same

(75) Inventor: Shunji Nakamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/589,104

(22) Filed: Oct. 30, 2006

Related U.S. Application Data
(62) Division of application No. 10/342,179, filed on Jan. 15, 2003.

(30) Foreign Application Priority Data
Mar. 12, 2002 (JP) 2002-67098

(51) Int. Cl. H01L 23/48; H01L 21/4763

(52) U.S. Cl. 257/774; 438/619; 257/776; 257/E23.145

(57) ABSTRACT

The semiconductor device comprises one layer including interconnections 32a to 32d formed above a substrate 10, and an insulation layer 34 formed over said one layer, a cavity 40 being included in said one layer. The dummy interconnection is removed by etching, whereby the layer can be planarized while the parasitic capacitance between the interconnections can be made small. Furthermore, the dielectric constant of the air in the cavity is much smaller than that of the inter-layer insulation film, whereby in comparison with the parasitic constant of the case where the inter-layer insulation film are formed simply between interconnections, the parasitic constant between the interconnections of the present invention can be made smaller.

### CROSS-REFERENCE TO RELATED APPLICATION

This application is a divisional of application Ser. No. 10/342,179, filed Jan. 15, 2003, which is based upon and claims priority of Japanese Patent Application No. 2002-67098, filed on Mar. 12, 2002, the contents being incorporated herein by reference.

### BACKGROUND OF THE INVENTION

The present invention relates to a semiconductor device and a method for fabricating the semiconductor device, more specifically to a semiconductor device which can realize higher operational speed and high-frequency characteristics and a method for fabricating the semiconductor device.

Recently, semiconductor devices are increasingly higher-integrated. Integrated semiconductor devices have interconnections formed in multi-layers. The semiconductor devices having the interconnections formed in multilayers have dummy interconnections, etc. in addition to the ordinary interconnections so as to ensure plainess of the respective layers.

The conventional semiconductor device will be explained with reference to FIGS. 29A and 29B. FIGS. 29A and 29B are diagrammatic views of the conventional semiconductor device. FIG. 29A is a plan view, and FIG. 29B is a sectional view.

As shown in FIGS. 29A and 29B, element isolation regions 214 for defining element regions 212 are formed on the surface of a semiconductor substrate 210. Transistors 224 comprising gate electrodes 218 and a source/drain diffused layer 220 are formed in the element regions 212.

An inter-layer insulation film 226 is formed on the semiconductor substrate 210 with the transistors 224 formed on. Contact plugs 230 are buried in the inter-layer insulation film 226, connected to the source/drain diffused layer 220. Interconnections 232 and dummy interconnection 239 are formed on the inter-layer insulation film 226 with the contact plugs 230 buried in. The dummy interconnection 239 is for ensuring plainess of respective layers.

Dummy pad 298 is formed on the inter-layer insulation film 226. The dummy pad 298 is also for ensuring plainess of the respective layers.

Inter-layer insulation films 234, 246, 254, 266 are formed on the inter-layer insulation film 226. Interconnection layers 244, 252, 264, dummy interconnection layers 251, 259, 267, and dummy pads 302, 306 are buried in the inter-layer insulation films 234, 246, 254, 266. An Electrode pad 271 is formed above the regions where the dummy pads 298, 302, 306 are formed. Wire 276 is bonded to the electrode pad 271.

The conventional semiconductor device has such constitution.

However, in the conventional semiconductor device shown in FIGS. 29A and 29B, the dummy interconnections, which are formed between the interconnections, make a parasitic capacitance among the interconnection-layers large. The dummy pads 298, 302, 306, which are formed on the respective layers between the electrode pad 271 and the semiconductor substrate 210, makes a parasitic capacitance between the electrode pad 271 and the semiconductor substrate 210 large. In the conventional semiconductor device, the large parasitic capacitance of the interconnections and the electrode pad have been a factor for blocking further improvement of the operational speed and high frequency characteristics.

### SUMMARY OF THE INVENTION

An object of the present invention is to provide a semiconductor device which can realize further improvement of the operational speed and high frequency characteristics and a method for fabricating the semiconductor device.

According to one aspect of the present invention, there is provided a semiconductor device comprising: one layer formed above a substrate, said one layer including an interconnection; and an insulation layer formed over said one layer, a cavity being formed in said one layer below the insulation layer.

According to another aspect of the present invention, there is provided a semiconductor device comprising: an electrode pad formed above a substrate; and an insulation layer formed between the substrate and the electrode pad, a cavity being formed in the insulation layer.

According to further another aspect of the present invention, there is provided a semiconductor device comprising: a coil of an inductor formed above a substrate; and an insulation layer formed over the coil, a cavity being formed adjacent to the coil and below the insulation layer.

According to further another aspect of the present invention, there is provided a semiconductor device comprising: a coil of an inductor formed above a substrate; and an insulation layer formed over the coil, a cavity being formed at the core of the inductor and below the insulation layer.

According to further another aspect of the present invention, there is provided a semiconductor device comprising an inductor formed above a substrate, a coil of the inductor comprising a plurality of first conductor formed in a first layer above the substrate, a plurality of second conductors formed in a second layer above the first layer, and a plurality of contact plugs buried in an insulation film formed between the first layer and the second layer and electrically connected to the first conductors and the second conductors, which are generally formed in helixes; and a cavity being formed at the core of the inductor.

According to further another aspect of the present invention, there is provided a method for fabricating a semiconductor device comprising the steps of: forming an interconnection and a dummy interconnection above a substrate; forming an insulation layer over the interconnection and the dummy interconnection; forming an opening in the insulation layer down to the dummy interconnection; and etching off the dummy interconnection through the opening to form a cavity.

According to further another aspect of the present invention, there is provided a method of fabricating a semiconductor device comprising the steps of: forming a dummy pad above a substrate; forming an insulation layer on the dummy pad; forming an opening in the insulation layer down to the dummy pad; and etching off the dummy pad through the opening to form a cavity.

As described above, according to the present invention, the dummy interconnection is removed by etching, whereby the respective layer can be planarized while the parasitic capacitance between the interconnections can be made small. Furthermore, the dielectric constant of the air in the cavity is much smaller than that of the inter-layer insulation film, whereby in comparison with the parasitic constant of the case where the inter-layer insulation film is formed simply between interconnections, the parasitic constant between the interconnections of the present invention can be made smaller. Thus, according to the present invention, the semiconductor device can be made speedy.

According to the present invention, the dummy pad below the electrode pad is removed by etching, whereby the parasitic capacitance between the electrode pad and the semiconductor substrate can be made small. Furthermore, the dielectric constant of the air in the cavity is much smaller than that of the inter-layer insulation film, whereby in comparison with the parasitic constant of the case where the inter-layer insulation film is formed simply between interconnections, the parasitic constant between the interconnections of the present invention can be made smaller. Thus, according to the present invention, the semiconductor device which can realize higher operational speed and improved high frequency characteristics can be provided.

According to the present invention, the cavity is formed adjacent the coil of the inductor, whereby the parasitic constant of the inductor can be small. According to the present invention, the cavity is formed at the core of the inductor, whereby the high frequency characteristics of the inductors can be improved. Thus, according to the present invention, the semiconductor device having good high frequency characteristics can be provided.

### BRIEF DESCRIPTION OF THE DRAWINGS

FIG. 1 is a sectional view of the semiconductor device according to a first embodiment of the present invention.

FIGS. 2A to 2C are sectional views of the semiconductor device according to the first embodiment of the present invention in the steps of the method for fabricating the same, which show the method (Part 1).

FIGS. 3A and 3B are sectional views of the semiconductor device according to the first embodiment of the present invention in the steps of the method for fabricating the same, which show the method (Part 2).

FIGS. 4A and 4B are sectional views of the semiconductor device according to the first embodiment of the present invention in the steps of the method for fabricating the same, which show the method (Part 3).

FIGS. 5A and 5B are sectional views of the semiconductor device according to the first embodiment of the present invention in the steps of the method for fabricating the same, which show the method (Part 4).

FIG. 6 is a sectional view of the semiconductor device according to the first embodiment of the present invention in the steps of the method for fabricating the same, which show the method (Part 5).

FIG. 7 is a sectional view of the semiconductor device according to the first embodiment of the present invention in the steps of the method for fabricating the same, which show the method (Part 6)

FIGS. 8A to 8C are diagrammatic views of the semiconductor device according to a second embodiment of the present invention.

FIGS. 9A to 9C are sectional views and a plane view of the semiconductor device according to the second embodiment of the present invention in the steps of the method for fabricating the same, which show the method (Part 1).

FIGS. 10A to 10C are sectional views of the semiconductor device according to the second embodiment of the present invention in the steps of the method for fabricating the same, which show the method (Part 2).

FIGS. 11A and 11B are sectional views of the semiconductor device according to the second embodiment of the present invention in the steps of the method for fabricating the same, which show the method (Part 3).

FIGS. 12A and 12B are a sectional view and a plane view of the semiconductor device according to the second embodiment of the present invention in the steps of the method for fabricating the same, which show the method (Part 4).

FIGS. 13A and 13B are sectional views of the semiconductor device according to the second embodiment of the present invention in the steps of the method for fabricating the same, which show the method (Part 5).

FIGS. 14A to 14C are sectional views of the semiconductor device according to a modification of the second embodiment of the present invention in the steps of the method for fabricating the same, which show the method (Part 1).

FIGS. 15A and 15B are sectional views of the semiconductor device according to the modification of the second embodiment of the present invention in the steps of the method for fabricating the same, which show the method (Part 2).

FIGS. 16A and 16B are sectional views of the semiconductor device according to the modification of the second embodiment of the present invention in the steps of the method for fabricating the same, which show the method (Part 3).

FIG. 17 is sectional views of the semiconductor device according to the modification of the second embodiment of the present invention in the steps of the method for fabricating the same, which show the method (Part 4).

FIGS. 18A and 18B are diagrammatic views of the semiconductor device according to a third embodiment of the present invention.

FIGS. 19A and 19B are sectional views of the semiconductor device according to the third embodiment of the present invention in the steps of the method for fabricating the same, which show the method (Part 1).

FIGS. 20A and 20B are sectional views of the semiconductor device according to the third embodiment of the present invention in the steps of the method for fabricating the same, which show the method (Part 2).

FIGS. 21A and 21B are sectional views of the semiconductor device according to the third embodiment of the present invention in the steps of the method for fabricating the same, which show the method (Part 3).

FIGS. 22A and 22B are diagrammatic views of the semiconductor device according to a fourth embodiment of the present invention.

FIGS. 23A and 23B are sectional views of the semiconductor device according to the fourth embodiment of the present invention in the steps of the method for fabricating the same, which show the method (Part 1).

FIGS. 24A and 24B are sectional views of the semiconductor device according to the fourth embodiment of the present invention in the steps of the method for fabricating the same, which show the method (Part 2).

FIGS. 25A and 25B are sectional views of the semiconductor device according to the fourth embodiment of the present invention in the steps of the method for fabricating the same, which show the method (Part 3).

FIGS. 26A and 26B are sectional views of the semiconductor device according to the fourth embodiment of the present invention in the steps of the method for fabricating the same, which show the method (Part 4).

FIGS. 27A and 27B are sectional views of the semiconductor device according to the fourth embodiment of the present invention in the steps of the method for fabricating the same, which show the method (Part 5).

FIGS. 28A and 28B are sectional views of the semiconductor device according to the fourth embodiment of the present invention in the steps of the method for fabricating the same, which show the method (Part 6).

FIGS. 29A and 29B are diagrammatic views of the conventional semiconductor device.

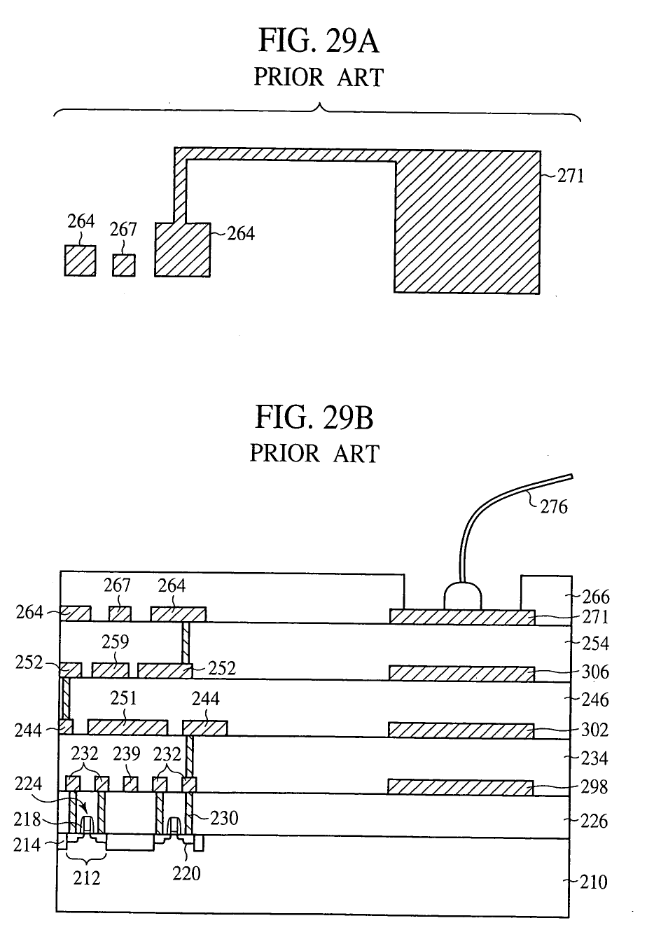

### DETAILED DESCRIPTION OF THE INVENTION

### A First Embodiment

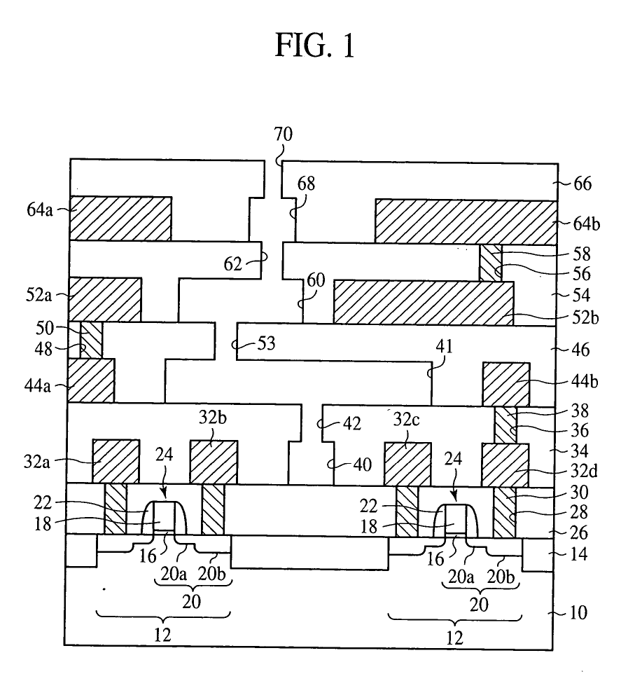

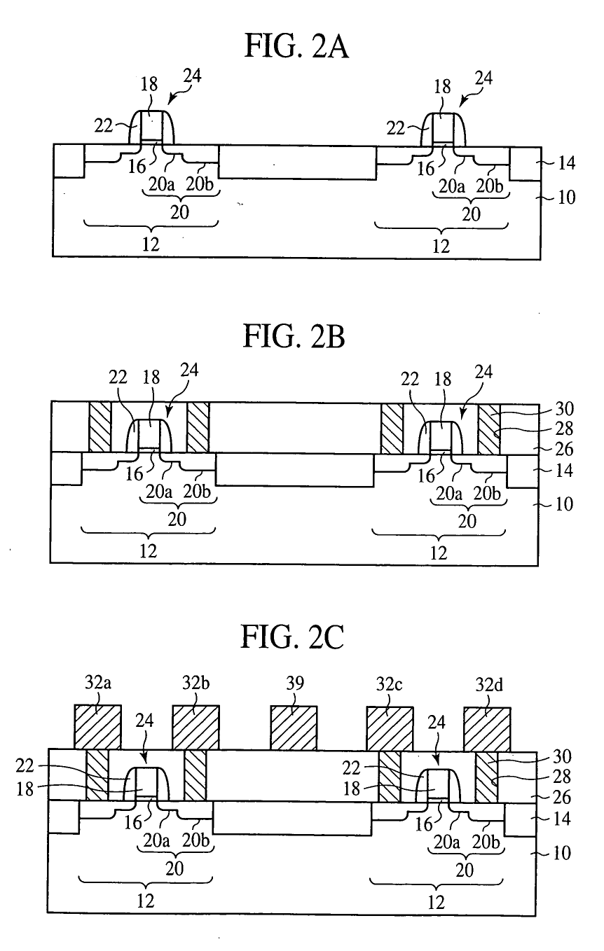

The semiconductor device according to a first embodiment of the present invention and the method for fabricating the semiconductor device will be explained with reference to FIGS. 1 to 7. FIG. 1 is a sectional view of the semiconductor device according to the present embodiment. FIGS. 2A to 7 are sectional views of the semiconductor device according to the present embodiment in the steps of the method for fabricating the semiconductor device, which show the method.

(The Semiconductor Device)

First the semiconductor device according to the present embodiment will be explained with reference to FIG. 1.

As shown in FIG. 1, element isolation regions 14 for defining element regions 12 are formed on the surface of a semiconductor substrate 10 of, e.g., silicon.

In the element regions 12, gate electrodes 18 of, e.g., polysilicon are formed with a gate insulation film 16 formed between the gate electrodes 18 and the semiconductor substrate 10.

A lightly doped diffused layer 20a is formed in the element region 12 on both sides of the gate electrode 18 by self-alignment with the gate electrode 18.

A sidewall insulation film 22 of, e.g., a silicon nitride film is formed on the side walls of the gate electrodes 18.

A heavily doped diffused layer 20b is formed in the element regions 12 on both sides of the gate electrodes 18 with the sidewall insulation film 22 formed on by self-alignment with the gate electrodes 18 with the sidewall insulation film 22 formed on.

The lightly doped diffused layer 20a and the heavily doped diffused layer 20b constitute a source/drain diffused layer 20.

Thus, transistors 24 comprising the gate electrodes 18 and the source/drain diffused layer 20 are constituted.

An inter-layer insulation film 26 of, e.g., SiO₂ is formed on the semiconductor substrate 10 with the transistors 24 formed on. In the inter-layer insulation film 26, contact holes 28 are formed down to the source/drain diffused layers 20. Contact plugs 30 are buried in the contact holes 28.

Interconnections 32a to 32d of, e.g. Al are formed on the inter-layer insulation film 26 with the contact plugs 30 buried in.

An inter-layer insulation film 34 of, e.g., SiO₂ is formed on the inter-layer insulation film 26 with the interconnections 32a to 32d formed on.

A contact hole 36 is formed in the inter-layer insulation film 34 down to the interconnection 32d. A contact plug 38 is buried in the contact hole 36.

A cavity 40 is formed between the interconnection 32b and the interconnection 32c. The cavity 40 is formed by etching off dummy interconnection 39 which will be described later (see FIG. 2C). The dummy interconnection 39 and the interconnections 32a to 32d are formed by etching one and the same conducting film, whereby the dummy interconnection 39 and the interconnections 32a to 32d have the same height. The cavity 40 is formed by etching off the dummy interconnection 39, whereby the cavity 40 and the interconnections 32a to 32d have the same height.

An opening 42 is formed in the inter-layer insulation film 34 down to the cavity 40.

Interconnections 44a, 44b of, e.g., Al are formed on the inter-layer insulation film 34. The interconnection 44b is connected to the contact plug 38.

An inter-layer insulation film 46 of, e.g., SiO₂ is formed on the inter-layer insulation film 34 with the interconnections 44a, 44b formed on.

A contact hole 48 is formed in the inter-layer insulation film 46 down to the interconnection 44a. A contact plug 50 is buried in the contact hole 48.

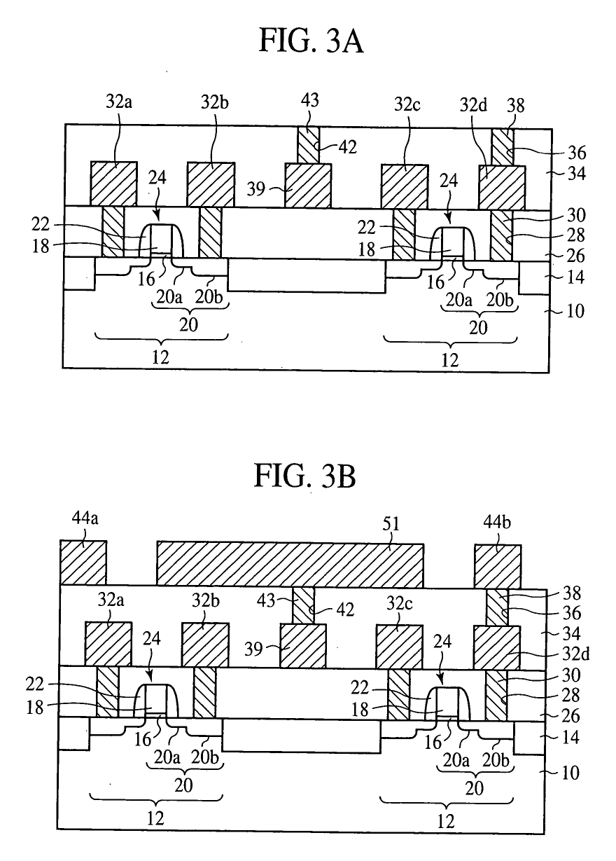

A cavity 41 is formed between the interconnection 44a and the interconnection 44b. The cavity 41 is formed by etching off dummy interconnection 51 which will be described later (see FIG. 3B). The dummy interconnection 51 and the interconnections 44a, 44b are formed by etching off one and the same conducting film, whereby the dummy interconnection 51 and the interconnections 44a, 44b have the same height. The cavity 41 is formed by etching off the dummy interconnection 51, whereby the cavity 41 and the interconnections 44a, 44b have the same height. The cavity 41 is in communication with the cavity 40 through the opening 42. Opening 53 is formed in the inter-layer insulation film 46 down to the cavity 41.

Interconnections 52a, 52b of, e.g., Al are formed on the inter-layer insulation film 46. The interconnection 52a is connected to the contact plug 50.

An inter-layer insulation film 54 of, e.g., SiO₂ is formed on the inter-layer insulation film 46 with the interconnections 52a, 54b formed on.

A contact hole 56 is formed in the inter-layer insulation film 54 down to the interconnection 52b. A contact plug 58 is buried in the contact hole 56.

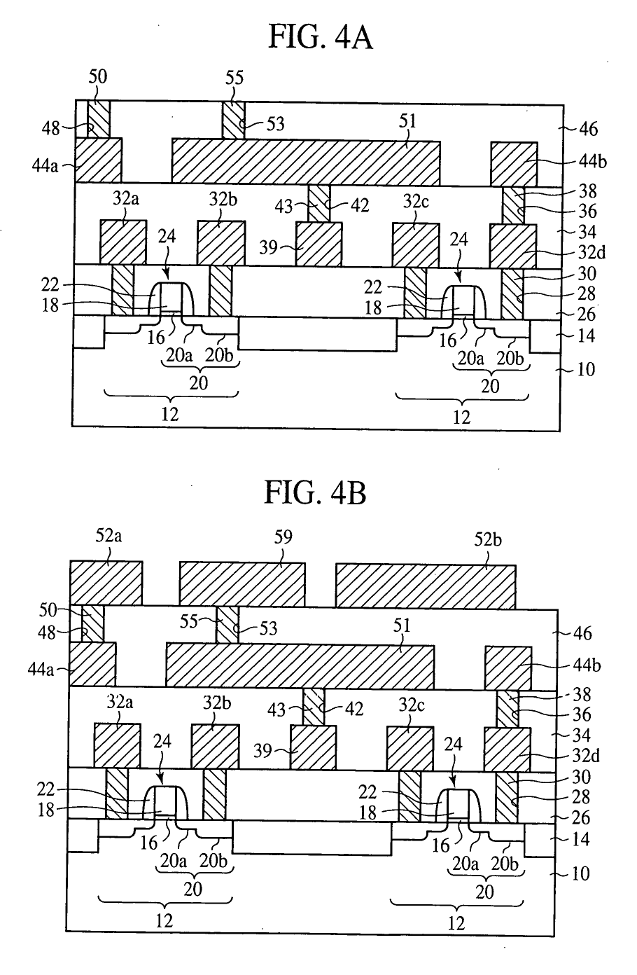

A cavity 60 is formed between the interconnection 52a and the interconnection 52b. The cavity 60 is formed by etching off dummy interconnection 59 which will be described later (see FIG. 4B). The dummy interconnection 59 and the interconnections 52a, 52b are formed by etching the one and the same conducting film, whereby the dummy interconnection 59 and the interconnections 52a, 52b have the same height. The cavity 60 is formed by etching off the dummy interconnection 59, whereby the cavity 60 and the interconnections 52a, 52b have the same height. The cavity 60 is in communication with the cavity 41 through the opening 53.

An opening 62 is formed in the inter-layer insulation film 54 down to the cavity 60.

Interconnections 64a, 64b are formed on the inter-layer insulation film 54. The interconnection 64b is connected to the contact plug 58.

An inter-layer insulation film 66 is formed on the inter-layer insulation film 54 with the interconnections 64a, 64b formed on.

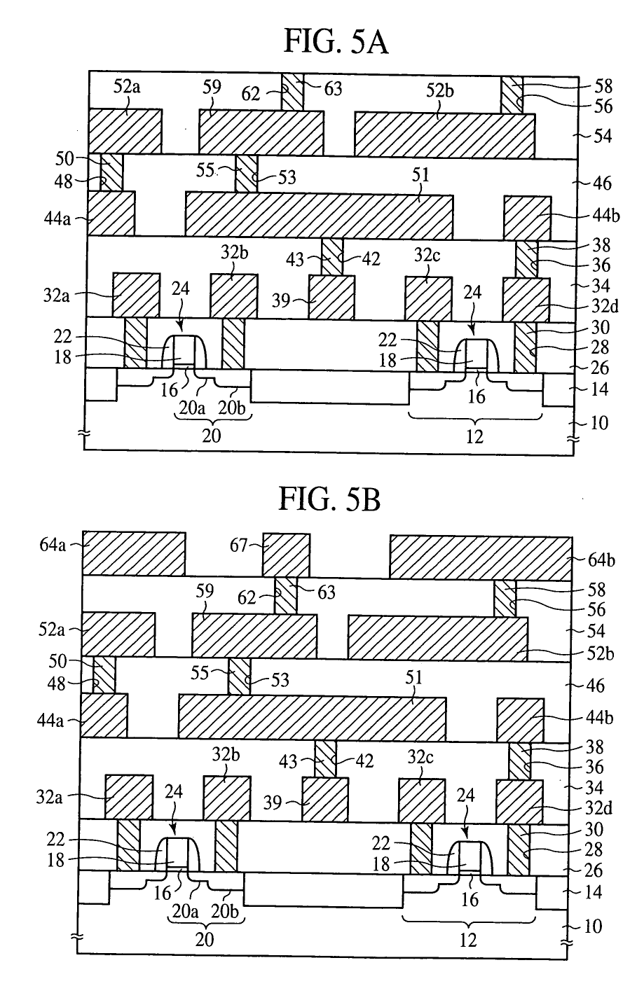

A cavity 68 is formed between the interconnection 64a and the interconnection 64b. The cavity 68 is formed by etching off dummy interconnection 67 which will be described later (see FIG. 5B). The dummy interconnection 67 and the interconnections 64a, 64b are formed by etching off the one and the same conducting film, whereby the dummy interconnection 67 and the interconnections 64a, 64b have the same height. The cavity 68 is formed by etching off the dummy interconnection 67, whereby the cavity 68 and the interconnections 64a, 64b have the same height. The cavity 68 is in communication with the cavity 60 through the opening 62.

An opening 70 is formed in the inter-layer insulation film 66 down to the cavity 68.

Thus, the semiconductor device according to the present embodiment is constituted.

The semiconductor device according to the present embodiment is characterized mainly in that the dummy interconnection is etched off to thereby form the cavity between the interconnections.

In the conventional semiconductor device, the dummy electrode is formed between the interconnections so as to planarize the respective layers, which makes the parasitic capacitance between the interconnections large. This is a factor which blocks further speedy operation of the semiconductor device.

In contrast to this, according to the present embodiment, the dummy interconnection is etched off, which permits the parasitic capacitance between the interconnections to be small. Furthermore, the dielectric constant of the air in the cavity is about 1, which is about ¼ of a dielectric constant of the inter-layer insulation film. Accordingly, in the present embodiment, the parasitic capacitance between the interconnections can be smaller than in the case that the inter-layer insulation film is simply buried between the interconnections. The dummy interconnection is formed between the interconnections at the time the inter-layer insulation film is formed on the interconnections, whereby the planarization of the respective layers is not hindered.

As described above, according to the present embodiment, the respective layers can be planarized while parasitic capacitance between the interconnections can be small. Furthermore, a dielectric constant of the air in the cavity is much smaller than that of the inter-layer insulation films, which permits parasitic capacitance between the interconnections to be smaller in comparison with those in the case that the inter-layer insulation film is formed between the interconnections. Thus, the semiconductor device according to the present embodiment can realize higher operational speed-up.

(The Method for Fabricating the Semiconductor Device)

Then, the method for fabricating the semiconductor device according to the present embodiment will be explained with reference to FIGS. 2A to 7.

First, as shown in FIG. 2A, the element isolation regions 14 for defining the element regions 12 are formed by STI (Shallow Trench Isolation).

Then, the gate insulation film 16 of SiO₂ is formed on the surface of the semiconductor substrate 10 by, e.g., thermal oxidation.

Next, a 200 nm-thickness polysilicon layer is formed by, e.g., CVD. Then, the polysilicon layer is patterned to form the gate electrodes 18 of polysilicon.

Next, a dopant is implanted in the element regions 12 by ion implantation by self-alignment with the gate electrodes 18. The lightly doped diffused layers 20a are thus formed in the element regions 12 on both sides of the gate electrodes 18.

Next, a 30 nm-thickness silicon nitride film is formed. Then, the silicon nitride film is anisotropically etched to form the sidewall insulation film 22 of the silicon nitride film on the sidewalls of the gate electrodes 18. The sidewall insulation film 22 is formed of silicon nitride film here but may be formed of silicon oxide film.

Then, a dopant is implanted in the element regions 12 by self-alignment with the gate electrodes 18 with the sidewall insulation films 22 formed on the sidewalls.

Thus, the source/drain diffused layers 20 of LDD (Lightly Doped Drain) structure formed of the lightly doped diffused layer 20a and the heavily doped diffused layer 20b.

The transistors 24 comprising the gate electrodes 18 and the source/drain diffused layer 20 are thus formed.

Next, as shown in FIG. 2B, the inter-layer insulation film 26 of a 500 nm-thickness SiO₂ film is formed on the entire surface by, e.g., CVD. Then, the surface of the inter-layer insulation film 26 is planarized by CMP (Chemical Mechanical Polishing)

Then, the contact holes 28 are formed in the inter-layer insulation film 26 down to the source/drain diffused layers 20.

Next, the contact plugs 30 of, e.g., polysilicon are buried in the contact holes 28.

Then, a Ti film, a TiN film and an Al film are sequentially laid on the entire surface by, e.g., sputtering. A thickness of the Ti film is, e.g., 10 nm. A thickness of the TiN film is, e.g., 20 nm. A thickness of the Al film is, e.g., 500 nm. Thus, a layer film of Al/TiN/Ti structure is formed. Then, the layer film is patterned by photolithography. Thus, as shown in FIG. 2C, the interconnections 32a to 32d and the dummy interconnection 39 of the Al/TiN/Ti structure are formed.

The dummy interconnection 39 is to be etched off in a later step. The dummy interconnection 39 must be isolated from the ordinary interconnections 32a to 32d for preventing even the ordinary interconnections 32a to 32d from being etched off in etching off the dummy interconnection 39 in the later step.

Then, as shown in FIG. 3A, the inter-layer insulation film 34 of a 1 μm-thickness SiO₂ film on the entire surface by, e.g., CVD. Then, the surface of the inter-layer insulation film 34 is planarized by CMP.

Next, the opening 42 and the contact hole 36 are formed in the inter-layer insulation film 34 respectively down to the dummy interconnection 39 and the interconnection 32d. The opening 42 must be formed down to the dummy interconnection 39, because an etchant for etching the dummy interconnection 39 arrives at the dummy interconnection 39 through the opening 42.

Then, the dummy plug 43 of, e.g., Al is buried in the opening 42, and the contact plug 38 of, e.g., Al is buried in the contact hole 36. The dummy plug 43 is to be etched off together with the dummy interconnection 39 in the later step.

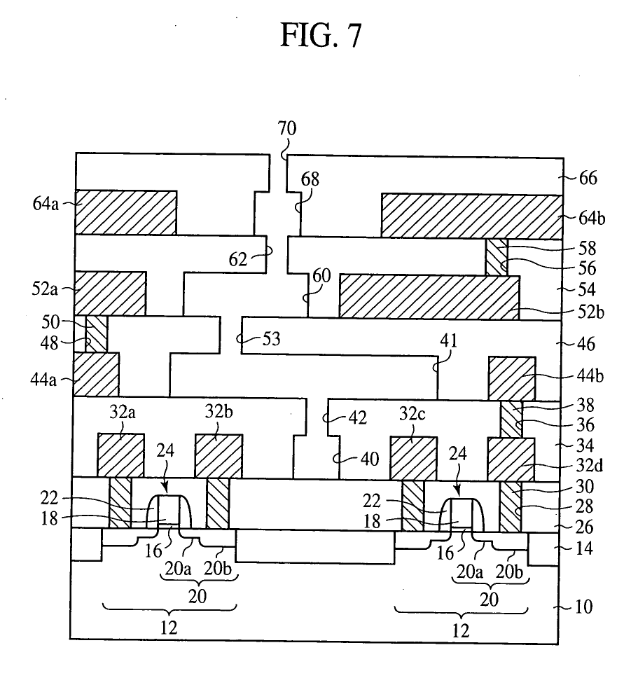

Next, an Al film of, e.g., a 500 nm-thickness is formed on the entire surface by, e.g. sputtering. Then, the Al film is patterned by photolithography. Thus, as shown in FIG. 3B, the interconnections 44a, 44b and the dummy interconnection 51 of Al are formed. The dummy interconnection 51 must be connected to the dummy plug 43, because an etchant for etching off the dummy interconnection 39 and the dummy plug 43 arrives at the dummy plug 43 and the dummy interconnection 39 through the cavity 41 (see FIG. 7) formed by etching off the dummy interconnection 51.

Next, as shown in FIG. 4A, the inter-layer insulation film 46 of a 1 μm-thickness SiO₂ film is formed on the entire surface by, e.g., CVD.

Next, the contact hole 48 and the opening 53 are formed in the inter-layer insulation film 46 respectively down to the interconnection 44a and the dummy interconnection 51. The opening 53 must be formed down to the dummy interconnection 51, because an etchant for etching off the dummy interconnection 51, etc. in the later step arrives at the dummy interconnection 51, etc. through the opening 53.

Then, the dummy plug 55 of, e.g., Al is buried in the opening 53, and the contact plug 50 of, e.g., Al is buried in the contact hole 48. The dummy plug 55 is to be etched off together with the dummy interconnection 39, 51 in the later step, as are the dummy plug 43.

Next, an Al film of, e.g., a 500 nm-thickness is formed on the entire surface by, e.g., sputtering. Then, the Al film is patterned by photolithography. Thus, as shown in FIG. 4B, the interconnections 52a, 52b and the dummy interconnection 59 of Al are formed. The dummy interconnection 59 must be connected to the dummy plug 55, because an etchant for etching off the dummy plug 55, the dummy interconnection 51, etc. in the later step through the cavity 60 (see FIG. 7) formed by etching off the dummy interconnection 59.

Then, as shown in FIG. 5A, the inter-layer insulation film 54 of a 1 μm-thickness SiO₂ film on the entire surface by, e.g., CVD.

Next, the opening 62 and the contact hole 56 are formed in the inter-layer insulation film 54 respectively down to the dummy interconnection 59 and the interconnection 52b. The opening 62 is formed down to the dummy interconnection 59, because an etchant for etching off the dummy interconnection 59, etc. in the later step arrives at the dummy interconnection 59, etc. through the opening 62.

Then, the dummy plug 63 of, e.g., Al is buried in the opening 62, and the contact plug 58 of, e.g., Al is buried in the contact hole 56. The dummy plug 63 is removed together with the dummy interconnection 59, etc. in a later step, as are the dummy plug 55.

Next, an Al film of, e.g., a 500 nm-thickness is formed on the entire surface by, e.g., sputtering. Then, the Al film is patterned by photolithography. Thus, as shown in FIG. 5B, the interconnections 64a, 64b and the dummy interconnection 67 of Al are formed. The dummy interconnection 67 must be connected to the dummy plug 63, because an etchant for etching off the dummy plug 63, the dummy interconnection 59, etc. in the later step arrives at the dummy plug 63, the dummy interconnection 59, etc. through the cavity 68 (see FIG. 7) formed by etching off the dummy interconnection 67.

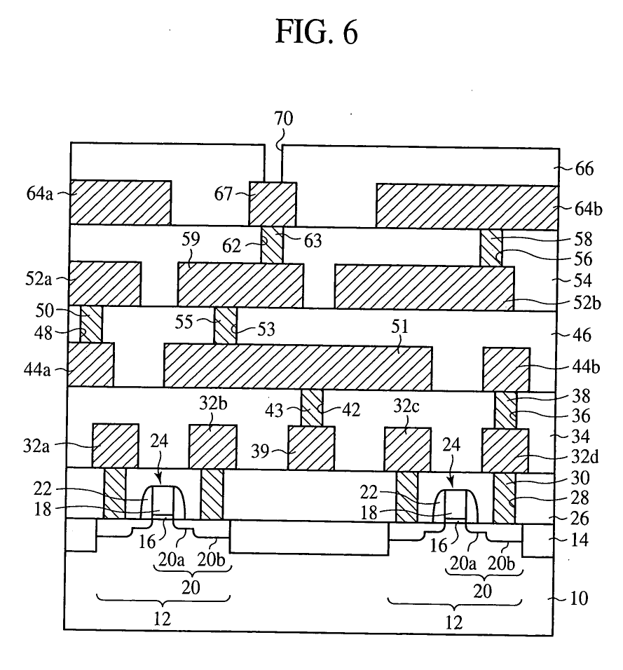

Next, as shown in FIG. 6, the inter-layer insulation film 66 of a 1 μm-thickness SiO₂ film on the entire surface by, e.g., CVD.

Then, the opening 70 is formed in the inter-layer insulation film 66 down to the dummy interconnection 67.

Next, as shown in FIG. 7, the dummy interconnection 67, the dummy plug 63, the dummy interconnection 59, the dummy plug 55, the dummy interconnection 51, the dummy plug 43 and the dummy interconnection 39 are wet-etched. The etchant entering through the opening 70 goes on etching sequentially these dummy interconnections and the dummy plugs, which are connected with each other. Finally, all these dummy interconnections and dummy plugs are etched. The cavities 40, 41, 60, 68 are formed in the portions from which the dummy interconnections 39, 51, 59, 67 have been etched off.

Thus, the semiconductor device according to the present embodiment is fabricated.

The dummy interconnections 39, 51, 59, 67 are completely removed in the present embodiment described above but may be partially left in a range which does not hinder the formation of the cavities. For example, only the parts of Al film of the dummy interconnection 39 of the Al/TiN/Ti structure are etched off while the TiN film and the Ti film may be left not etched. The TiN film and the Ti film remain on the bottoms of the cavity 40 but do not hinder the formation of the cavities 40, 41, 60, 68. No remarkable problem takes place.

The etching using sulfuric acid or hydrochrolic acid can remove Al alone. The etching using a mixed liquid of hydrogen peroxide and sulfuric acid can remove not only the Al film but also the TiN film and the Ti film.

### A Second Embodiment

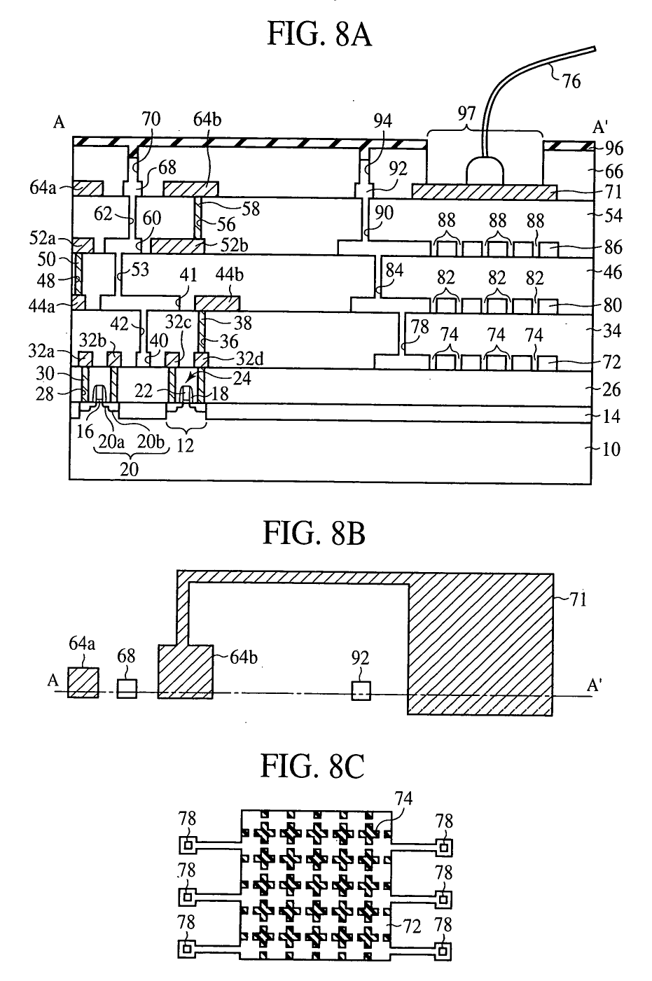

The semiconductor device according to a second embodiment of the present invention and the method for fabricating the semiconductor device will be explained with reference to FIGS. 8A to 13B. FIGS. 8A to 8c are diagrammatic views of the semiconductor device according to the present embodiment. The same members of the present embodiment as those of the semiconductor device according to the first embodiment shown in FIGS. 1 to 7 and the method for fabricating the same are represented by the same reference numbers not to repeat or to simplify their explanation.

(The Semiconductor Device)

First, the semiconductor device according to the present embodiment will be explained with reference to FIGS. 8A to 8C. FIG. 8A is a sectional view of the semiconductor device according to the present embodiment. FIG. 8B is a plan view of the semiconductor device, which shows the electrode pad. FIG. 8A is the sectional view along the line A-A′ in FIG. 8B. FIG. 8C is a plan view of the semiconductor device, which shows the cavity.

The semiconductor device according to the present embodiment is characterized mainly in that dummy pad is removed by etching, and the cavity is formed below the electrode pad.

The left side of the drawing of FIG. 8A has the same as the constitution of the semiconductor device according to the first embodiment described above, and its explanation is omitted.

As shown on the right side of the drawing of FIG. 8A, cavity 72 is formed in an inter-layer insulation film 34 below the electrode pad 71. The cavity 72 is formed by etching off dummy pad which will be described later. Interconnections 32a to 32d and the dummy pads are formed by etching one and the same conducting film, whereby a height of the dummy pads is equal to a height of the interconnections 32a to 32d. As described above, the cavity 72 is formed by etching off the dummy pad, whereby a height of the cavity 72 is equal to a height of the interconnections 32a to 32d.

As shown in FIG. 8C, a plurality of pillars 74 are formed in the cavity 72. In other words, the cavity 72 is divided in a plurality of sections by the plurality of pillars 74. The pillars 74 are formed of the same insulation film as the inter-layer insulation film 34. The plurality of pillars 74 are formed in the cavity 72 for the purpose of ensuring the strength of the inter-layer insulation film 34. When wire 76 is bonded to the electrode pad 71, large forces are applied to the inter-layer insulation films 34, 46, 54 below the electrode pad 71. With the cavity simply formed without the pillars below the electrode pad 71, the strength of the inter-layer insulation film below the electrode pad 71 is small, with a risk that the inter-layer insulation film may be broken in the bonding. According to the present embodiment, because of the pillars 74 in the cavity 72, the inter-layer insulation film below the electrode pad 71 is prevented from breaking in the bonding.

The pillars 74 are not necessary when the strength of the inter-layer insulation film 34 is sufficient.

A plurality of openings 78 are formed in the inter-layer insulation film 34 down to the cavity 72 (see FIG. 8C). The plurality of openings 78 are formed to enable the dummy pad to be etched efficiently and without failure when the dummy pad is etched.

A cavity 80 is formed in an inter-layer insulation film 46 below the electrode pad 71. As will be described later, the cavity 80 is formed by etching off the dummy pad, whereby a height of the cavity 80 is equal to a height of interconnections 44a, 44b. The cavity 80 is in communication with the cavity 72 through the openings 78.

A plurality of pillars 82 are formed in the cavity 80 for the same reason as described above.

Openings 84 are formed in the inter-layer insulation film 46 down to the cavity 80.

A cavity 86 is formed in an inter-layer insulation film 64 below the electrode pad 71. As will be described later, the cavity 86 is formed by etching off a dummy pad. A height of the cavity 86 is equal to a height of interconnections 52a, 52b. The cavity 86 is in communication with the cavity 80 through the openings 84. A plurality of pillars 88 are formed in the cavity 86 for the same reason as described above.

Openings 90 are formed in an inter-layer insulation film 54 down to the cavity 86.

The electrode pad 71 of, e.g., Al is formed on the inter-layer insulation film 54. The electrode pad 71 is connected to the interconnection 64b as shown in FIG. 8B.

A opening 97 is formed in the inter-layer insulation film 66 down to the electrode pad 71.

A cavity 92 is formed in the inter-layer insulation film 66. As will be described later, the cavity 92 is formed by etching off a dummy layer 93, whereby a height of the cavity 92 is equal to a height of the electrode pad 71. The cavity 92 is in communication with the cavity 86 through openings 90.

The opening 94 is opened in the inter-layer insulation film 66 down to the cavity 92.

A cap layer 96 of, e.g., Si₃N₄ is formed on the inter-layer insulation film 66. The cap layer 96 is for preventing water from intruding into the device through the openings 70, 94.

Thus, the semiconductor device according to the present embodiment is constituted.

The semiconductor device according to the present embodiment is characterized mainly in that the cavity is formed below the electrode pad 71.

In the conventional semiconductor device, the dummy pads are formed on the respective layers below the electrode pad for planarization of the respective layers. Accordingly, a parasitic capacitance between the electrode pad and the semiconductor substrate is very large. A large capacitance between the electrode pad and the semiconductor substrate is a barrier factor for higher frequencies of signals.

In the present embodiment, however, the dummy pads below the electrode pad 71 is etched off, whereby the parasitic capacitance between the electrode pad 71 and the semiconductor substrate 10 can be small. Furthermore, a dielectric constant of the air in the cavity is much smaller than that of the inter-layer insulation film, whereby the parasitic capacitance can be made smaller in comparison with the parasitic capacitance in the case that the inter-layer insulation films are formed simply between the electrode pad 71 and the semiconductor substrate 10. Thus, the semiconductor device according to the present embodiment can realize higher operational speed and higher frequencies.

(The Method for Fabricating the Semiconductor Device)

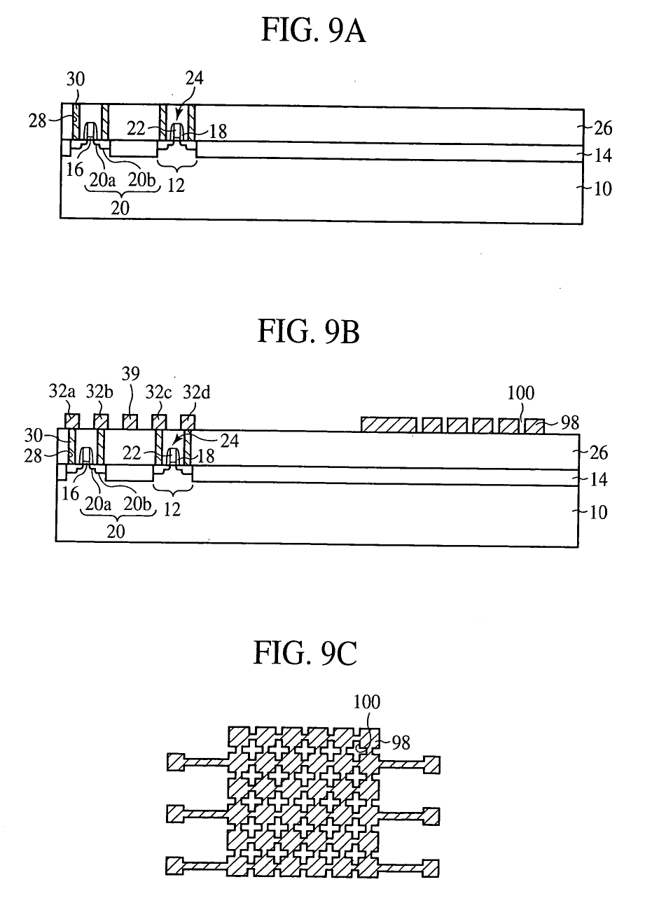

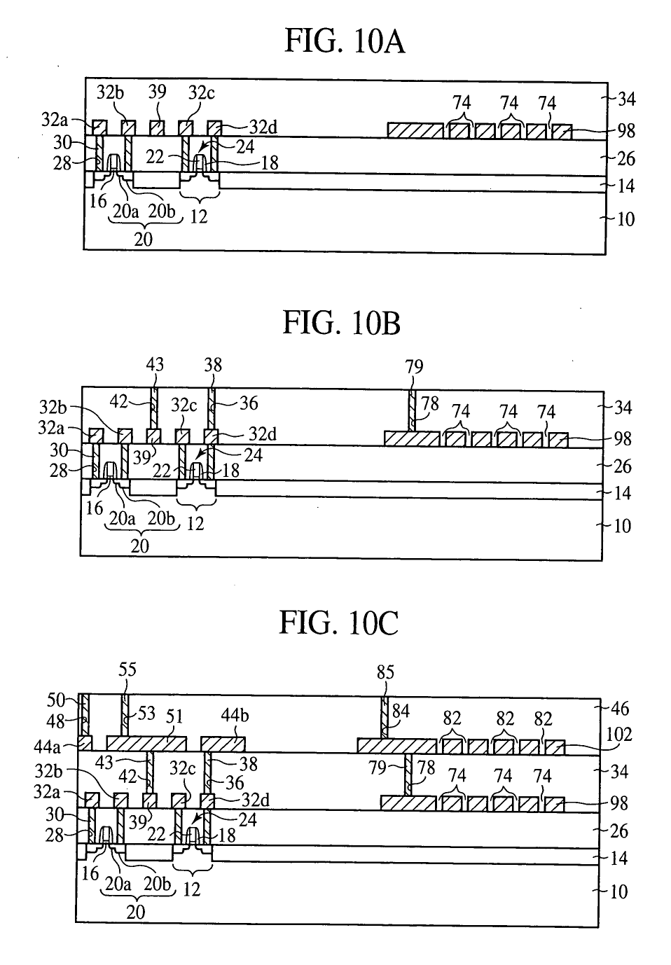

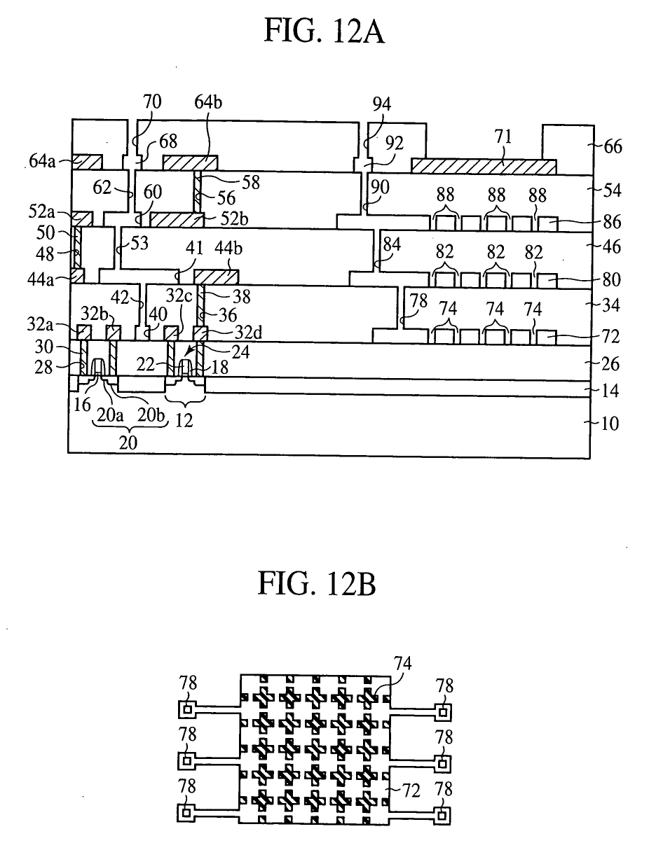

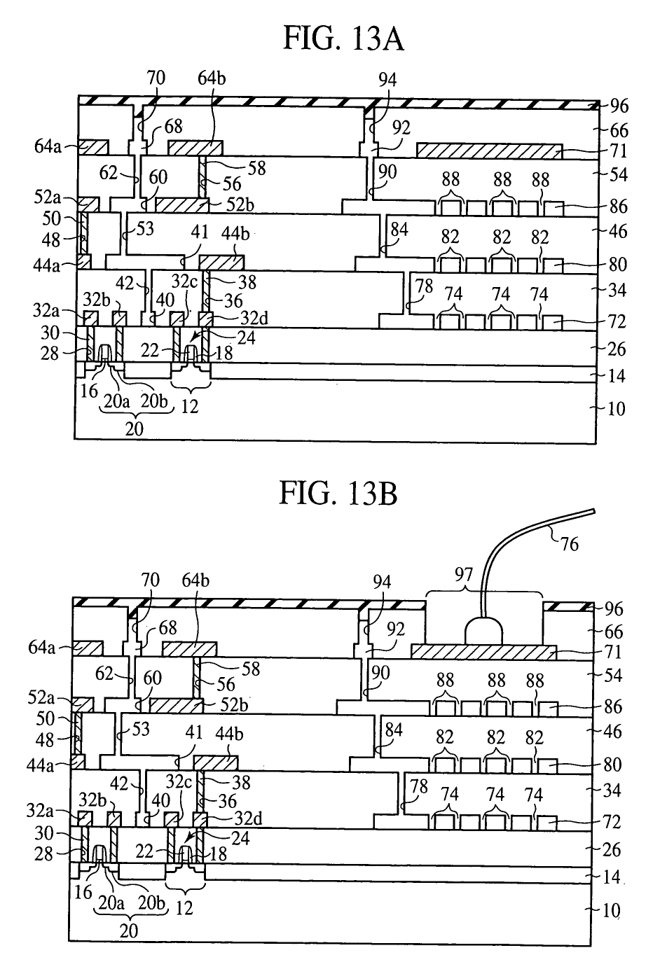

Next, the method for fabricating the semiconductor device according to the present embodiment will be explained with reference to FIGS. 9A to 13B. FIGS. 9A to 13B are sectional views of the semiconductor device according to the present embodiment in the steps of the method for fabricating the same, which show the method. FIGS. 9A and 9B are sectional views, and FIG. 9C is a plan view. FIGS. 10A to 12A are sectional views, and FIG. 12B is a plan view. FIGS. 13A and 13B are sectional views.

The steps up to the step of burying the contact plugs 30 in the contact holes 28 including the contact plugs 30 burying step are the same as those of the method for fabricating the semiconductor device according to the first embodiment shown in FIGS. 2A to 2B, and their explanation are omitted (FIG. 9A).

Next, a Ti film, a TiN film and an Al film are sequentially formed on the entire surface by, e.g., sputtering. A thickness of the Ti film is, e.g., 10 nm. A thickness of the TiN film is, e.g., 20 nm. A thickness of the Al film is, e.g., 500 nm. A layer film of the Al/TiN/Ti structure is thus formed. Then, the layer film is patterned by photolithography. Thus, as shown in FIG. 9B, the interconnections 32a to 32d and the dummy interconnection 39 of the Al/TiN/Ti structure are formed, and the dummy pad 98 of the Al/TiN/Ti structure is formed. At this time, as shown in FIG. 9C, openings 100 are formed in the dummy pad 98. The openings 100 are formed in the dummy pad 98 so as to form the pillars 74 of the inter-layer insulation film 34 in the openings 100 in a later step.

Then, the inter-layer insulation film 34 is formed in the same way as described above with reference to FIG. 3A (FIG. 10A). Thus, the pillars 74 of the inter-layer insulation film 34 are buried in the openings 100 of the dummy pad 98.

Next, as shown in FIG. 10B, in the inter-layer insulation film 34, the opening 42 and the contact hole 36 are formed respectively down to the dummy interconnection 39 and the down to the interconnection 32d, and openings 78 are formed down to the dummy pad 98. The openings 78 are formed down to the dummy pad 98 so that when the dummy pad 98 is etched in a later step, an etchant arrives at the dummy pad 98 through the openings 78.

The openings 78 are formed in a plural number as described above (see FIG. 8C). A plurality of the openings 78 are formed so that when the dummy pad 98 is etched, the dummy pad 98 can be etched efficiently and without failure. When the dummy pad 98 can be etched without failure through one opening 78, one opening 78 may be provided.

Then, the contact plug 38 of, e.g., Al is buried in the contact hole 36 while the dummy plugs 43, 79 of, e.g., Al are buried in the openings 42, 78.

Then, an Al film is formed on the entire surface by, e.g., sputtering. Then, the Al film is patterned by photolithography. Thus, the interconnections 44a, 44b and the dummy interconnection 51 of Al are formed while the dummy pad 102 is formed of Al. Openings are formed also in the dummy pad 102, as are formed the openings 100 in the dummy pad 98.

At this time, the dummy pad 102 is formed to be connected to the dummy plugs 79. The dummy pad 102 is connected to the dummy plugs 79 so that an etchant for etching the dummy plugs 79 and the dummy pad 98 arrives at the dummy plugs 79 and the dummy pad 98 through the cavity 80 (see FIGS. 12A and 12B) formed in the inter-layer insulation film 46.

Then, in the same way as described above with reference to FIG. 4A, the inter-layer insulation film 46 is formed (FIG. 10C). Thus, pillars 82 of the inter-layer insulation film 46 are buried in the openings formed in the dummy pad 102.

Next, the opening 53 and the contact hole 48 are formed in the inter-layer insulation film 46 respectively down to the dummy interconnection 51 and the interconnection 44a, and the openings 84 are formed down to the dummy pad 102. The openings 84 are formed down to the dummy pad 102 so that when the dummy pad 102 is etched in a later step, an etchant arrives at the dummy pad 102 through the openings 84.

The openings 84 are formed in a plural number, as are the openings 78. A plurality of the openings 84 are formed so that, as in forming a plurality of the openings 78, when the dummy pad 102 is etched, the dummy pad 102 can be etched efficiently and without failure.

Next, the contact plug 50 of, e.g., Al is buried in the contact hole 48 while the dummy plugs 55, 85 of, e.g., Al are buried in the openings 53, 84.

Then, an Al film is formed on the entire surface by, e.g., sputtering. Then, the Al film is patterned by photolithography. Thus, the interconnections 52a, 52b and the dummy interconnection 59 are formed of Al while the dummy pad 106 is formed of Al. At this time, openings are formed also in the dummy pad 106 for the same reason for forming the openings 100 in the dummy pad 98.

At this time, the dummy pad 106 is formed, connected to the dummy plugs 85. The dummy pad 106 is connected to the dummy plugs 85 so that an etchant for etching the dummy plugs 85, the dummy pad 102, etc. arrives at the dummy plugs 85, the dummy pad 102, etc. through the cavity 86 (see FIG. 12) formed in the inter-layer insulation film 54 by etching the dummy pad 106.

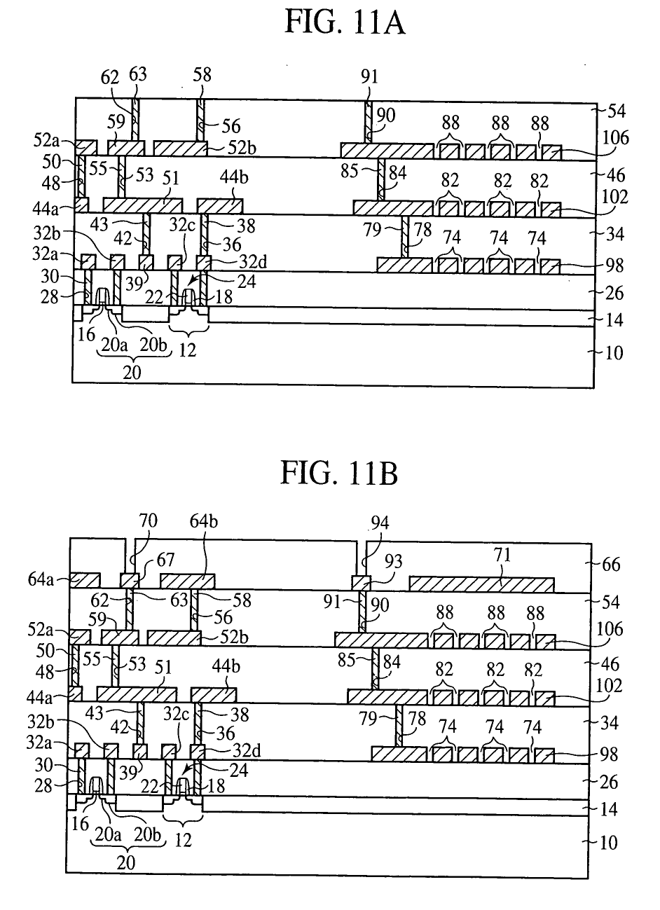

Then, in the same way as described above with reference to FIG. 5A, the inter-layer insulation film 54 is formed (FIG. 11A). The openings formed in the dummy pad 106 are filled with the pillars 88 of the inter-layer insulation film 54.

Next, in the inter-layer insulation film 54, the opening 62 and the contact hole 56 are formed respectively down to the dummy interconnection 59 and the interconnection 52b, and the openings 90 down to the dummy pad 106. The openings 90 are formed down to the dummy pad 106 so that an etchant arrives at the dummy pad 106, etc. through the openings 90 when the dummy pad 106, etc. is etched in a later step.

The openings 90 are formed in a plural number, as are the openings 78, 84. A plurality of the openings 90 are formed so that when the dummy pad 106 is etched in a later step, the dummy pad 106 can be etched efficiently and without failure, as are a plurality of the openings 78, 84 formed.

Then, the contact plug 63 of, e.g., Al is buried in the contact hole 62 while the dummy plugs 58, 91 of, e.g., Al are buried in the openings 56, 90.

Next, an Al film is formed on the entire surface by, e.g., sputtering. Then, the Al film is patterned by photolithography. Thus, as shown in FIG. 11B, the interconnections 64a, 64b, and the dummy interconnection 67 of Al are formed, and a dummy layer 93 and the electrode pad 71 of Al are formed.

At this time, the dummy layer 93 is formed, connected to the dummy plugs 91. The dummy layer 93 is contacted to the dummy plugs 91 so that an etchant for etching the dummy plugs 91, the dummy pad 106, etc. arrives at the dummy plugs 91, the dummy pad 106, etc. through the cavity 92 (see FIGS. 12A and 12B) formed in the inter-layer insulation film 66 by etching the dummy layer 93.

Then, the inter-layer insulation film 66 is formed in the same was as described above with reference to FIG. 6.

Next, in the inter-layer insulation film 66, the opening 94 is formed down to the dummy layer 93, and the opening 70 is formed down to the dummy interconnection 67.

Then, the dummy interconnection 67, the dummy plug 63, the dummy interconnection 59, the dummy plug 55, the dummy interconnection 51, the dummy plug 43 and the dummy interconnection 39 are wet-etched, and the dummy layer 93, the dummy plugs 91, the dummy pad 106, the dummy plugs 85, the dummy pad 102, the dummy plug 70 and the dummy pad 98 are etched. The etchant can be, e.g., hydrochloric acid, sulfuric acid, or others. The dummy layers, the dummy pads and the dummy plugs are connected with each other, whereby the dummy layers, the dummy pads and the dummy plugs are sequentially etched by the etchant entering the opening 94. Finally, the all these dummy layers, dummy pads and dummy plugs are etched.

As shown in FIGS. 12A and 12B, the cavities 92, 72, 80, 86 and the openings 78, 84, 90 are formed in the part from which the dummy layer 93, the dummy pads 98, 102, 106 and the dummy plugs 79, 95, 91 have been etched off. The pillars 74, 82, 88 of the inter-layer insulation films 34, 46, 54 are left, not etched, and as shown in FIGS. 12A, 12B, the cavities 72, 80, 86 are formed, divided respectively by the pillars 74, 82, 88.

Then, as shown in FIG. 13A, the cap layer 96 of, e.g., SiO₂ is formed on the entire surface by, e.g., CVD.

Next, as shown in FIG. 13B, an opening 97 is formed in the cap layer 96 and the inter-layer insulation film 66 down to the electrode pad 71 by photolithography. The opening 97 admit the wire 76 to be bonded to the electrode pad 71.

Thus, the semiconductor device according to the present embodiment is fabricated.

(Modification)

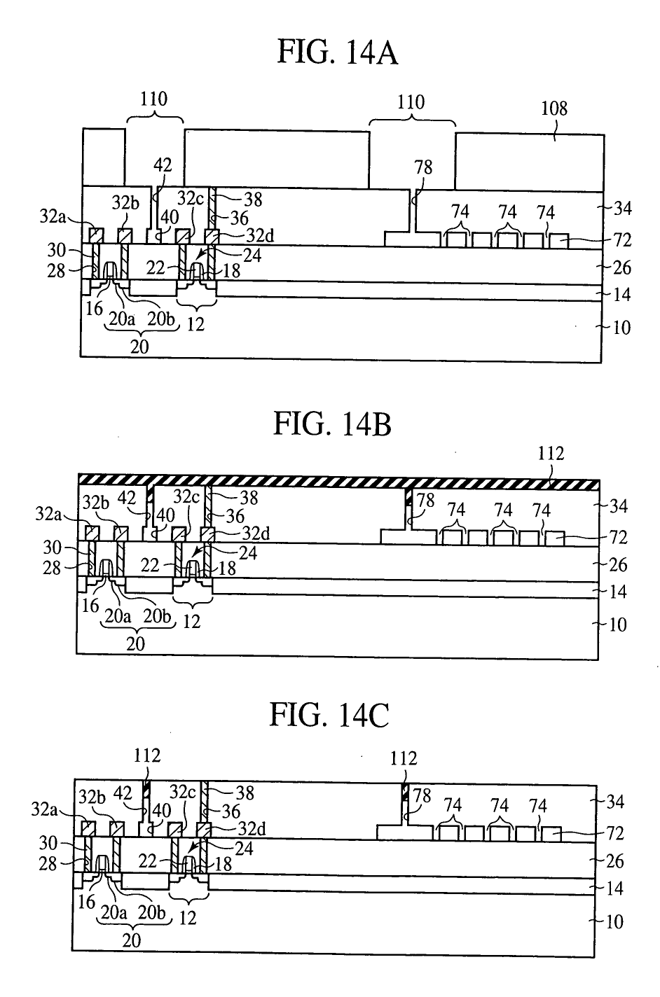

Next, a modification of the present embodiment will be explained with reference to FIGS. 14A to 17. FIGS. 14A to 17 are sectional views of the semiconductor device according to the present modification in the steps of the method for fabricating the same, which show the method.

The method for fabricating the semiconductor device according to the present modification is characterized mainly in that dummy interconnections, dummy pads, etc. are not etched at once as in the present embodiment but are etched layer by layer.

The steps up to the step of burying dummy plugs 43, 79 in openings 42, 78 and burying contact plug 38 in contact hole 36 including the dummy plugs and contact plugs burying step are the same as described above with reference to FIGS. 10A and 10B, and their explanation is omitted.

Next, as shown in FIG. 14A, a photoresist film 108 is formed on the entire surface by, e.g., spin coating. Then, the photoresist film 108 is patterned by photolithography. Thus, the photoresist film 108 has openings 110 formed for exposing the dummy plugs 43, 79.

Next, with the photoresist film 108 as a mask, the dummy plugs 43, 49, the dummy interconnection 39 and the dummy pad 98 are wet etched. An etchant can be, e.g., hydrochloric acid or others. Thus, cavities 40, 72 and openings 42, 78 are formed in the inter-layer insulation film 34.

Then, as shown in FIG. 14B, an insulation film 112 of, e.g., a 200 nm-thickness Si₃N₄ is formed on the entire surface by, e.g., CVD or spin coating. At this time, the insulation film 112 is formed, buried in parts of the openings 42, 78.

Next, the insulation film 112 is etched back. Thus, as shown in FIG. 14C, the insulation film 112 is buried in parts of the openings 42, 78. The insulation films 112 is buried in the openings 42, 78 so that an etchant does not enter cavities 40, 72 when the interconnections 44a, 44b, the dummy interconnection 51 and the dummy pad 102 are etched in a later step.

In the above-described embodiment, the dummy interconnection of a lower layer must be connected to the dummy interconnection of upper layers via the dummy plug. However, in the present modification, the cavities are formed layer by layer, which makes unnecessary to connect the dummy interconnections of a lower layer to the dummy interconnections of upper layers via the dummy plugs.

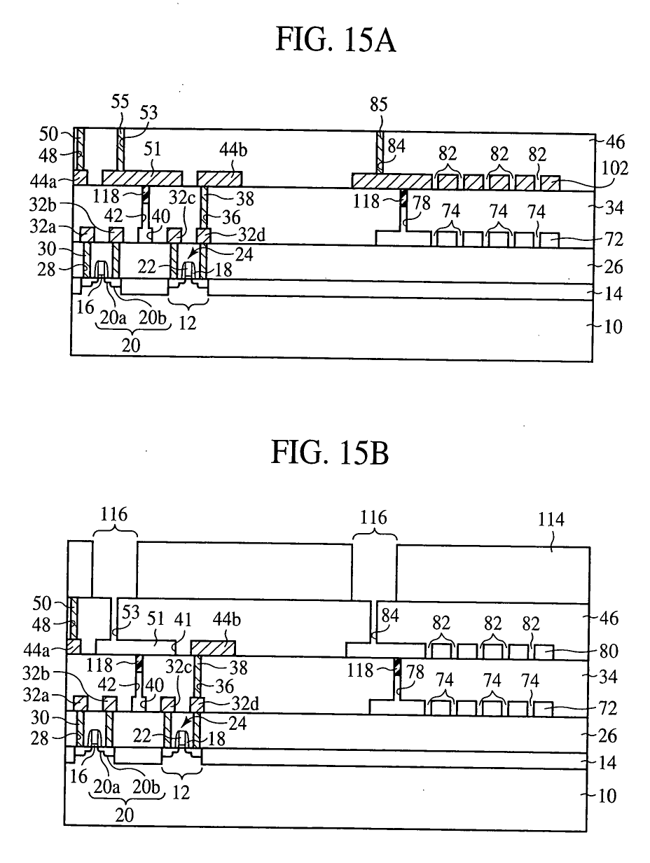

The following steps up to the step of burying the dummy plugs 55, 85 in the openings 53, 84 and burying contact plug 50 in contact hall 48 including the dummy plugs and contact plug burying step are the same as those described above with reference to FIG. 10C, and their explanation is omitted (FIG. 15A).

Next, in the same way as described above with reference to FIG. 14A, a photoresist film 114 is formed. Then, in the same way as described above with reference to FIG. 14A, openings 116 for exposing the dummy plugs 55, 85 are formed in the photoresist film 114.

Then, with the photoresist film 114 as a mask, the dummy plugs 55, 85, the dummy interconnection 39 and the dummy pad 102 are wet-etched. An etchant can be, e.g., hydrochloric acid or others. Thus, cavities 41, 80 and openings 53, 84 are formed in the inter-layer insulation film 46.

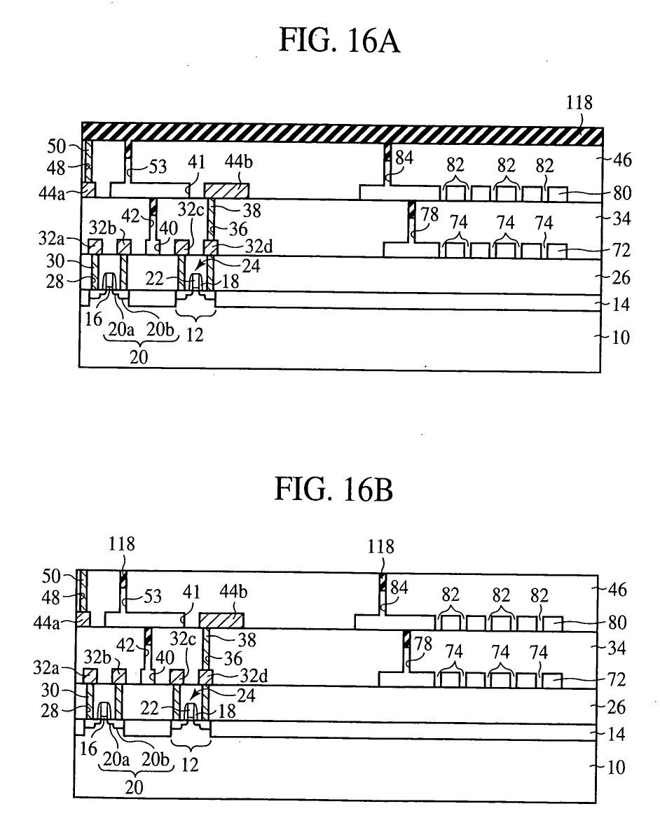

Next, as shown in FIG. 16A, an insulation film 118 of, e.g., a 200 nm-thickness Sii₃N₄ film is formed on the entire surface by, e.g., CVD or spin coating. At this time, the insulation film 118 is formed, buried in parts of the openings 53, 84.

Next, the insulation film 118 is etched back. Thus, as shown in FIG. 16B, the insulation film 118 is buried in the parts of the openings 53, 84. The insulation film 118 is buried in the openings 53, 84 so that an etchant does not enter the cavities 41, 80 when the interconnections 52a, 52b, the dummy interconnection 59 and the dummy pad 106 are etched.

The following steps up to the step of burying dummy plugs 63, 91 in the openings 62, 90 and burying contact plug 58 in the contact hall 56 including the dummy plugs and the contact plug burying step are the same as described above with reference to FIG. 11A, and their explanation is omitted.

Next, in the same way as described above with reference to FIG. 15B, a photoresist film (not shown) is formed. Then, as descried above with reference to FIG. 15B, openings (not shown) for exposing dummy plugs 63, 91 are formed in the photoresist film.

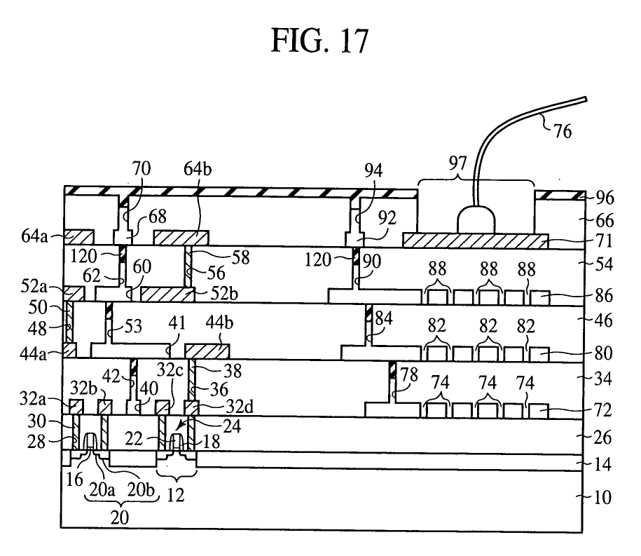

Then, with the photoresist film (not shown) as a mask, the dummy plugs 63, 91, the dummy interconnections 59 and the dummy pad 106 are wet-etched. An etchant can be, e.g., hydrochloric acid or others. Thus, as shown in FIG. 17, cavities 60, 80 and openings 62, 90 are formed in the inter-layer insulation film 54.

Next, as described above with reference to FIGS. 16A and 16B, an insulation film 120 is buried in the openings 62, 90.

The following steps are the same as described above with reference to FIGS. 11B to 13B, and their explanation is omitted.

Thus, the semiconductor device according to the present modification is fabricated.

As described above, the dummy interconnections, the dummy pads, etc. are etched layer by layer.

### A Third Embodiment

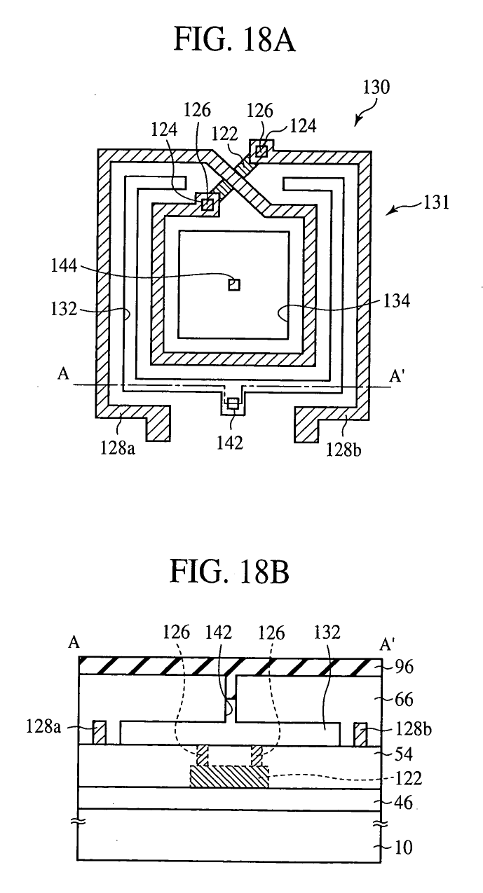

The semiconductor device according to a third embodiment of the present invention and the method for fabricating the same will be explained with reference to FIGS. 18A to 21B. FIGS. 18A and 18B are diagrammatic views of the semiconductor device according to the present embodiment. FIG. 18A is a plan view, and FIG. 18B is the sectional view along the line A-A′ in FIG. 18A. The same members of the present embodiment as those of the semiconductor device according to the first or the second embodiment shown in FIGS. 1 to 17 and the method for fabricating the same are represented by the same reference numbers not to repeat or to simplify their explanation.

(The Semiconductor Device)

The semiconductor device according to the present embodiment is characterized mainly in that the semiconductor device comprises an inductor, specifically a coil, a cavity formed adjacent to the coil of the inductor, and cavity is formed at the core of the coil.

As shown in FIGS. 18A and 18B, a conductor 122 is formed on an inter-layer insulation film 46.

An inter-layer insulation film 54 is formed on the inter-layer insulation film 46 with the conductor 122 formed on.

Contact holes 124 are formed in the inter-layer insulation film 54 each down to each of both ends of the conductor 122.

Contact plugs 126 are buried in the contact holes 124.

Conductors 128a, 128b are formed on the inter-layer insulation film 54 with the contact plugs 126 buried in.

The conductors 128a, 128b are connected to the conductor 122 respectively via the contact plugs 126.

The conductor 128a, the conductor 122 and the conductor 128b generally define a helix. The conductor 128a, the conductor 122 and the conductor 128b form the coil 131 of the inductor 130.

An inter-layer insulation film 66 is formed on the inter-layer insulation film 54 with the coil 131 of the conductor 128a, the conductor 122 and the conductor 128b formed on.

A cavity 132 is formed adjacent to the conductors 128a, 122 and 128b.

A cavity 134 is formed at the core of the inductor 130.

An opening 142 is formed in the inter-layer insulation film 66 down to the cavity 132. An opening 144 is formed in the inter-layer insulation film 66 down to the cavity 134. A cap layer 96 is formed on the inter-layer insulation film 66.

According to the present embodiment, the cavity 132 is formed adjacent to the coil 131 of the inductor 130, whereby the parasitic capacitance can be small. According to the present embodiment, the cavity 134 is formed at the core of the inductor 130, whereby the high frequency characteristics of the inductor 130 can be improved. Accordingly, the semiconductor device according to the present embodiment can have good high frequency characteristics.

In the present embodiment, the cavity 132 is formed adjacent to the coil 131, and the cavity 134 is formed at the core of the inductor. However, the cavity 132 alone or the cavity 134 alone may be formed.

(The Method for Fabricating the Semiconductor Device)

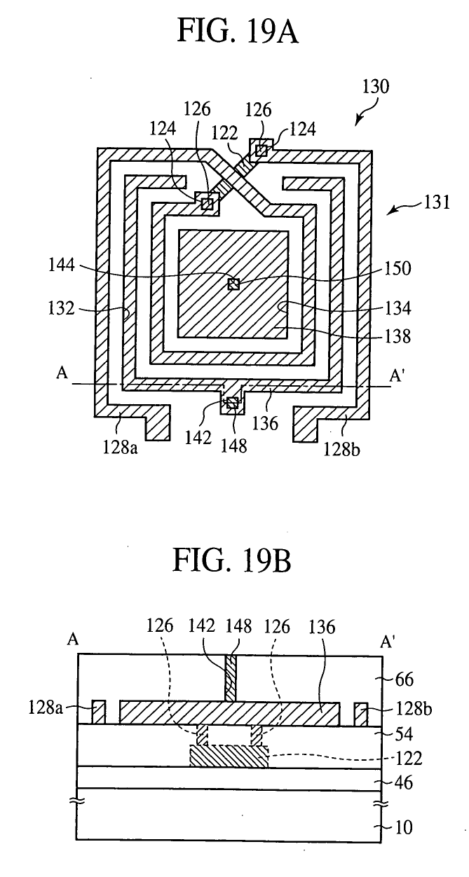

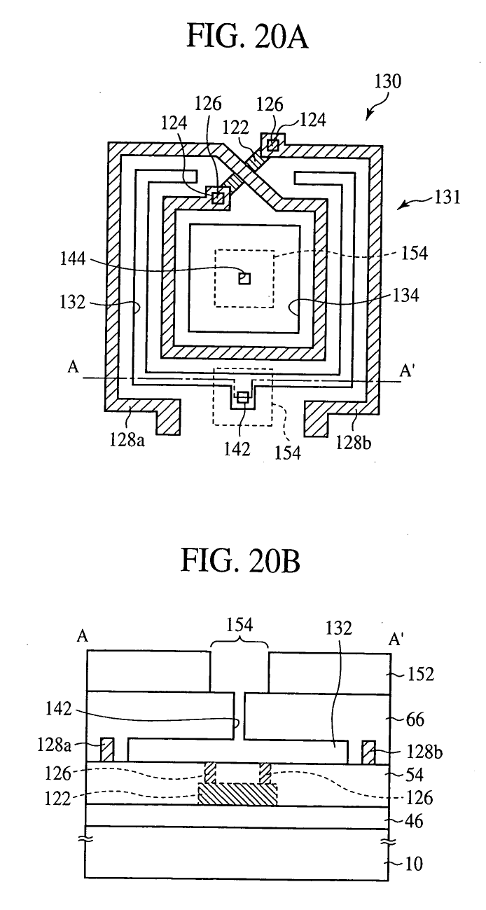

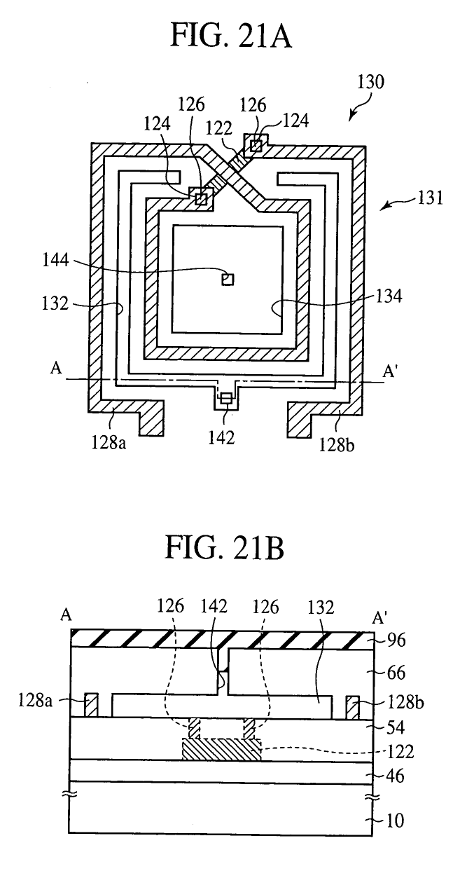

Next, the method for fabricating the semiconductor device according to the present embodiment will be explained with reference to FIGS. 19A to 21B. FIGS. 19A to 21B are sectional views of the semiconductor device according to the present embodiment in the steps of the method for fabricating the semiconductor device, which show the method. FIG. 19A is a plan view, and FIG. 19B is the sectional view along the line A-A′ in FIG. 19A. FIG. 20A is a plan view, and the FIG. 20B is the sectional view along the line A-A′ in FIG. 20A. FIG. 21A is a plan view, and FIG. 21B is the sectional view along the line A-A′ in FIG. 21A.

As shown in FIGS. 19A and 19B, the conductor 122 of, e.g., Al is formed on the inter-layer insulation film 46.

Next, the inter-layer insulation film 54 is formed on the entire surface.

Next, the contact holes 124 are formed in the inter-layer insulation film 54 each down to each of both ends of the conductor 122.

Then, the contact plugs 126 of, e.g., Al are buried in the contact holes 124.

Next, an Al film is formed on the entire surface by, e.g., sputtering. Then the Al film is patterned by photolithography. Thus, the conductors 128a, 128b of Al, a dummy layer 136 of Al and a dummy core layer 138 of Al are formed.

Next, the inter-layer insulation film 66 is formed on the entire surface.

Then, the opening 142 and the opening 144 are formed respectively down to the dummy layer 136 and down to the dummy core layer 138.

Next, dummy plugs 148, 150 of Al are buried in the openings 142, 144.

Then, as shown in FIGS. 20A and 20B, a photoresist film is formed by, e.g., spin coating. Then, openings 154 for exposing the dummy plugs 148, 150 are formed in the photoresist film by photolithography.

Next, with the photoresist film 152 as a mask, the dummy plugs 148, 150 and the dummy layer 136 and the dummy core layer 138 are etched. Thus, the cavities 132, 134 are formed in the inter-layer insulation film 166.

Next, as shown in FIGS. 21A and 21B, the cap layer 96 is formed on the entire surface by, e.g., CVD or spin coating.

Thus, the semiconductor device according to the present embodiment is fabricated.

### A Fourth Embodiment

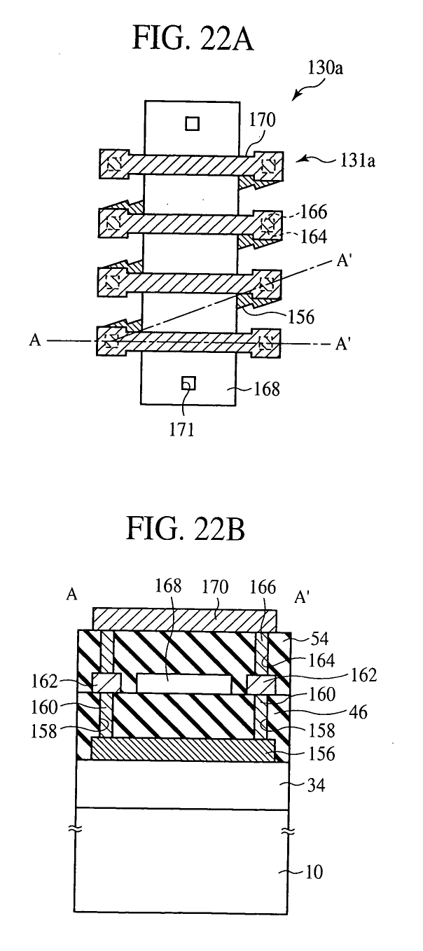

The semiconductor device according to a fourth embodiment of the present invention will be explained with reference to FIGS. 22A to 28B. FIGS. 22A and 22B are diagrammatic views of the semiconductor device according to the present embodiment. FIG. 22A is a plan view, and FIG. 22B is a sectional view. The same members of the present embodiment as those of the semiconductor device according to the first to the third embodiments and the method for fabricating the semiconductor device shown in FIGS. 1 to 21B are represented by the same reference numbers not to repeat or to simplify their explanation.

(The Semiconductor Device)

First, the semiconductor device according to the present embodiment will be explained with reference to FIGS. 22A and 22B.

The semiconductor device according to the present embodiment is characterized mainly in that an inductor, specifically a coil is formed in three dimensions, and a cavity is formed at the core of the inductor.

As shown in FIGS. 22A and 22B, a plurality of conductors 156 of, e.g., Al are formed on an inter-layer insulation film 34.

An inter-layer insulation film 46 is formed on the inter-layer insulation film 34 with the conductors 156 formed on.

In the inter-layer insulation film 46, a contact holes 158 are formed respectively down to the respective conductors 156. Contact plugs 160 are buried in the contact holes 158.

A conductor layer 162 is formed on the inter-layer insulation film 46 with the contact plugs 160 buried in.

An inter-layer insulation film 54 is formed on the inter-layer insulation film 46 with the conductor layer 162 formed on. Contact holes 164 are formed in the inter-layer insulation film 54 down to the conductor layers 162. Contact plugs 166 are buried in the contact holes 164.

A cavity 168 is formed in the inter-layer insulation film 54. Openings 171 are formed in the inter-layer insulation film 54 down to the cavity 168.

A plurality of conductors 170 of, e.g., Al are formed on the inter-layer insulation film 54 with the contact plugs 166 buried in. The respective conductors 170 are respectively connected to the contact plugs 166.

The conductors 156, the contact plugs 160, the conductor layer 162, conductor plugs 166, the conductors 170 are connected generally in helixes. The conductors 156, the contact plugs 160, the conductor layers 162, conductor plugs 166, the conductors 170 constitute coil 131a of the inductor 130a.

Thus, the semiconductor device according to the present embodiment is constituted.

According to the present embodiment, the cavity 168 is formed at the core of the inductor 130a, whereby the inductor 130a can have good high frequency characteristics. Thus, according to the present embodiment, even in a case the inductor 130a is formed in three-dimensions, the inductor 130a can have good high frequency characteristics. Thus, the semiconductor device having good high frequency characteristics can be provided.

(The Method for Fabricating the Semiconductor Device)

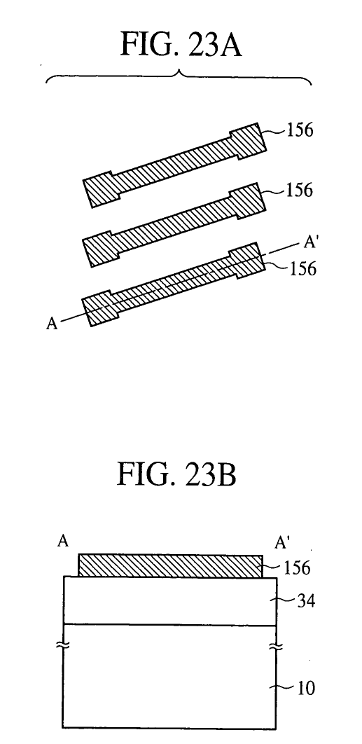

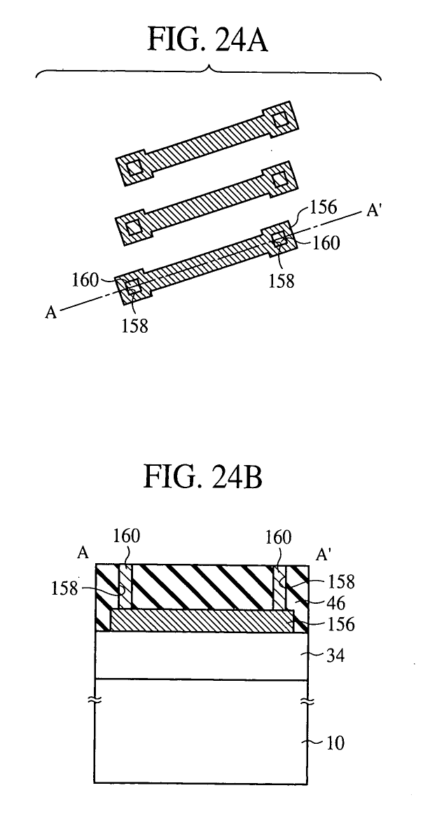

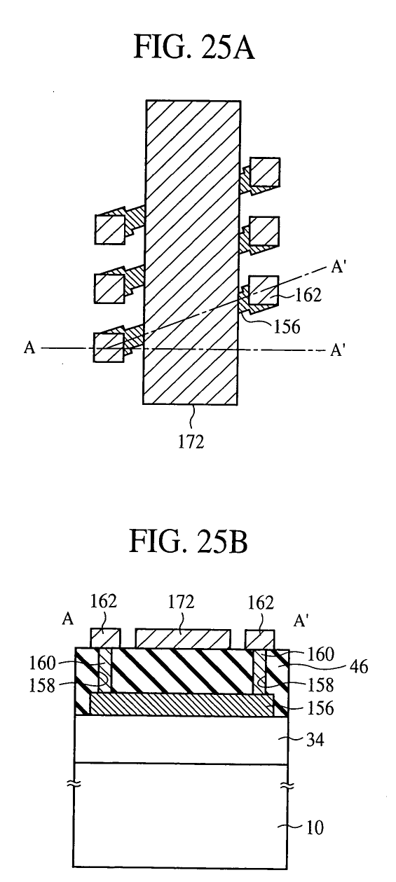

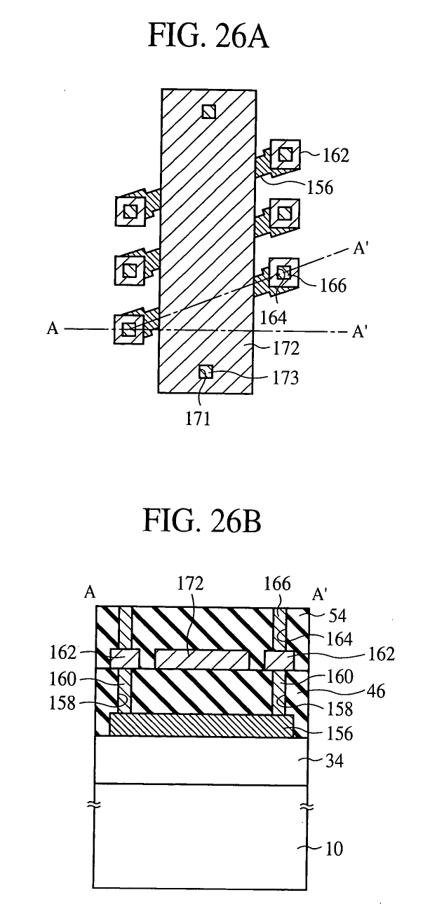

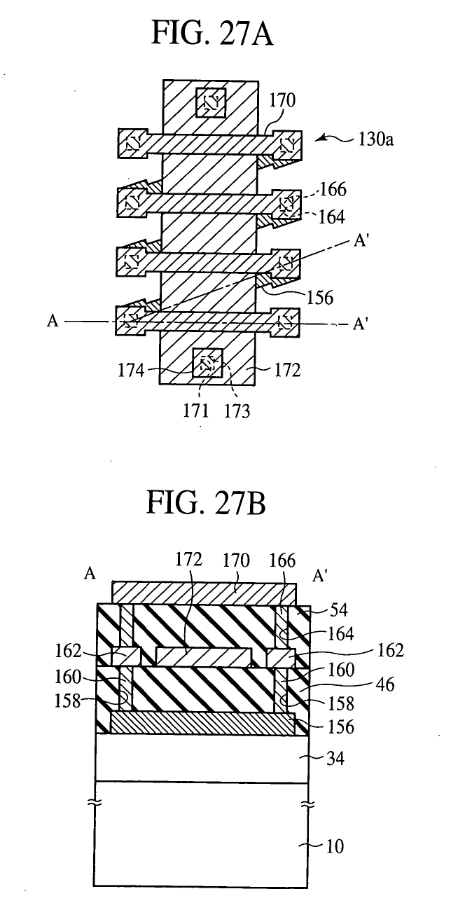

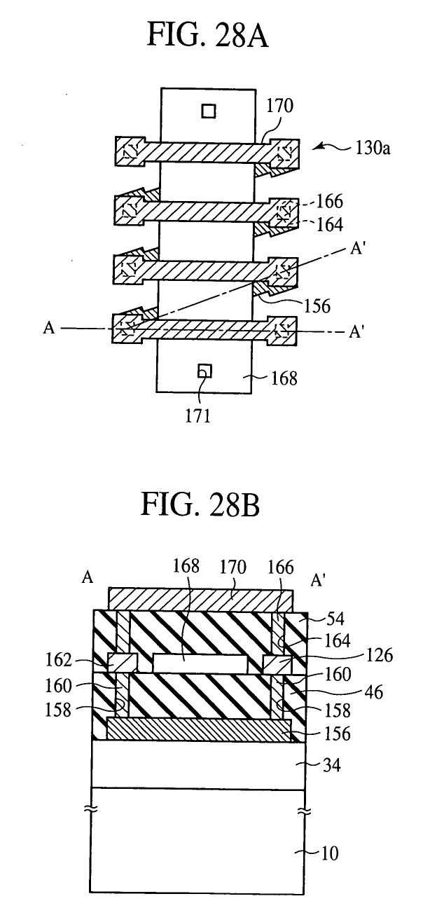

The method for fabricating the semiconductor device according to the present embodiment will be explained with reference to FIGS. 23A to 28B. FIGS. 23A to 28B are sectional views of the semiconductor device in the steps of the method for fabricating the same, which show the method. FIG. 23A is a plan view, and FIG. 23B is a sectional view. FIG. 24A is a plan view, and FIG. 24B is a sectional view. FIG. 25A is a plan view, and the FIG. 25B is a sectional view. FIG. 26A is a plan view, and FIG. 26B is a sectional view. FIG. 27A is a plan view, and FIG. 27B is a sectional view. FIG. 28A is a plan view, and FIG. 28B is a sectional view.

An Al film is formed on the inter-layer insulation film 34 by, e.g., sputtering. The Al film is patterned by photolithography. Thus, as shown in FIGS. 23A and 23B, a plurality of conductors 156 are formed of Al.

Next, the inter-layer insulation film 46, for example, is formed on the inter-layer insulation film 34 with the conductors 156 formed on.

Then, as shown in FIGS. 24A and 24B, the contact holes 158 are formed in the inter-layer insulation film 46 each down to each of both ends of the respective conductors 156. Then, the contact plugs 160 of, e.g., Al are buried in the contact holes 158.

Next, an Al film is formed on the entire surface by, e.g., sputtering. Then, the Al film is patterned by photolithography. Thus, as shown in FIGS. 25A and 25B, the conductor layers 162 and the dummy core layer 172 are formed.

Next, as shown in FIGS. 26A and 26B, the inter-layer insulation film 54 is formed on the entire surface.

Then, the contact holes 164 are formed in the inter-layer insulation film 54 down to the conductor layers 162, and the openings 171 are formed down to the dummy core layer 172.

Next, the contact plugs 166 of, e.g., Al are buried in the contact holes 164, and the dummy plugs 173 of, e.g., Al are buried in the openings 171.

Next, an Al film is formed on the entire surface by, e.g., sputtering. Then, the Al film is patterned by photolithography. Thus, as shown in FIGS. 27A and 27B, a plurality of conductors 170, 174 of Al are formed. At this time, each of both ends of the respective conductors 170 is connected to each of the contact plugs 166. The conductor layers 174 are formed, connected to the dummy plugs 173.

Next, a photoresist film (not shown) is formed on the entire surface by, e.g., spin coating. Then, the resist film is patterned by photolithography. Thus, openings (not shown) for exposing the conductor layer 174 are formed in the photoresist film.

Next, with the photoresist film as a mask, the conductor layer 174, the dummy plugs 173 and the dummy core layer 172 are etched. Thus, the cavity 168 is formed in the inter-layer insulation film 54 at the part thereof which is to be the core of the inductor 130a.

Thus, the semiconductor device according to the present embodiment is fabricated.

[Modifications]

The present invention is not limited to the above-described embodiments and can cover other various modifications.

For example, in the above-described embodiments, the dummy interconnections, the dummy plugs, the dummy pads, etc. are formed of Al, but their material is not limited to Al. Materials which can be etched off can be suitable used. For example, Cu, W, WN, Ti, TiN, Ta, TaN, Ag or others may be used.

In the modification of the second embodiment described above, the insulation film is buried in the openings, but what is buried in the openings is not limited to the insulation film. For example, a conductor film may be used.

What is claimed is:

1. A semiconductor device comprising:
a first insulation layer formed over a substrate;
a second insulation layer formed on the first insulation layer; and
a bonding pad formed over the second insulation layer,
wherein a cavity is formed in a lower part of the second insulation layer, the cavity being surrounded with the second insulation layer, and
the second insulation layer is contacted with the first insulation layer.

2. A semiconductor device according to claim 1, further comprising
an interconnection buried in the second insulation layer, and in which
a height of the cavity is substantially equal to a height of the interconnection.

3. A semiconductor device according to claim 1, wherein
a pillar is formed in the cavity.

4. A semiconductor device according to claim 1, wherein
the cavity is divided in a plurality of sections.

5. A semiconductor device according to claim 1, further comprising
a third insulation layer formed over the third insulation layer,
wherein the bonding pad is formed over the third insulation layer,
another cavity is formed in the third insulation layer, by etching another dummy pad formed on the second insulation layer.

6. A semiconductor device comprising:
a coil of an inductor formed above a substrate; and
an insulation layer formed over the coil,
a cavity being formed adjacent to the coil and below the insulation layer.

7. A semiconductor device comprising:
a coil of an inductor formed above a substrate; and
an insulation layer formed over the coil,
a cavity being formed at the core of the inductor and below the insulation layer.

8. A semiconductor device according to claim 6, wherein
a height of the cavity is substantially equal to a height of the coil.

9. A semiconductor device according to claim 7, wherein
a height of the cavity is substantially equal to a height of the coil.

10. A semiconductor device comprising an inductor formed above a substrate,
a coil of the inductor comprising a plurality of first conductor formed in a first layer above the substrate, a plurality of second conductors formed in a second layer above the first layer, and a plurality of contact plugs buried in an insulation film formed between the first layer and the second layer and electrically connected to the first conductors and the second conductors, which are generally formed in helixes; and
a cavity being formed at the core of the inductor.

11. A semiconductor device according to claim 1, wherein
an opening is formed in the second insulation layer down to the cavity.

12. A semiconductor device according to claim 6, wherein
an opening is formed in the insulation layer down to the cavity.

13. A semiconductor device according to claim 7, wherein
an opening is formed in the insulation layer down to the cavity.

14. A semiconductor device according to claim 10, wherein
an openings is formed in the insulation layer down to the cavity.

15. A method for fabricating a semiconductor device comprising the steps of:
forming an interconnection and a dummy interconnection above a substrate;
forming an insulation layer over the interconnection and the dummy interconnection; forming an opening in the insulation layer down to the dummy interconnection; and etching off the dummy interconnection through the opening to form a cavity.

16. A method of fabricating a semiconductor device comprising the steps of:
forming a dummy pad above a substrate;
forming an insulation layer on the dummy pad;
forming an opening in the insulation layer down to the dummy pad; and
etching off the dummy pad through the opening to form a cavity.

17. A method for fabricating a semiconductor device according to claim 16, further comprising the step of forming an electrode pad above the dummy pad.
